(19) United States
(12) Patent Application Publication
(10) Pub. No.: US 2017/0287866 A1
(43) Pub. Date: Oct. 5, 2017

(54) INTERLAYER FILLER COMPOSITION FOR SEMICONDUCTOR DEVICE AND METHOD FOR PRODUCING SEMICONDUCTOR DEVICE

(71) Applicant: Mitsubishi Chemical Corporation, Chiyoda-ku (JP)

(72) Inventors: Makoto IKEMOTO, Kitakyushu-shi (JP); Yasuhiro KAWASE, Kitakyushu-shi (JP); Hidehiro YAMAMOTO, Kitakyushu-shi (JP); Masaya SUGIYAMA, Kitakyushu-shi (JP)

(73) Assignee: Mitsubishi Chemical Corporation, Chiyoda-ku (JP)

(21) Appl. No.: 15/486,330

(22) Filed: Apr. 13, 2017

Related U.S. Application Data
(63) Continuation of application No. PCT/JP2015/078803, filed on Oct. 9, 2015.

(30) Foreign Application Priority Data
Oct. 14, 2014 (JP) 2014-209592

(51) Int. Cl. H01L 23/00

(52) U.S. Cl. CPC H01L 24/29; H01L 24/83; H01L 24/81; H01L 2224/2919; H01L 2224/83203; H01L 2224/81203; H01L 2924/0665; H01L 2924/364

(57) ABSTRACT

To provide an interlayer filler composition capable of forming a cured adhesive layer sufficiently cured and excellent in adhesion without letting voids be formed in the cured adhesive layer while minimizing leak out of a filler. An interlayer filler composition for a semiconductor device, comprises an epoxy resin (A), a curing agent (B), a filler (C) and a flux (D), has a minimum value of its viscosity at from 100 to 150° C. and satisfies the following formulae (1) and (2) simultaneously:

10<η50/η120<500 (1)

1,000<η150/η120 (2)

(wherein η50, η120 and η150 represent the viscosities at 50° C., 120° C. and 150° C., respectively, of the interlayer filler composition).

### TECHNICAL FIELD

The present invention relates to an interlayer filler composition for a semiconductor device, and a method for producing a semiconductor device using the interlayer filler composition.

### BACKGROUND ART

In recent years, in order to further improve the performance of semiconductor devices, in addition to refinement of transistors and wirings, research and development have been in progress for layered semiconductor devices having laminated a plurality of substrates such as semiconductor substrates or organic substrates having a semiconductor device layer formed thereon, by stacking them perpendicular to the substrate plane.

As a layered semiconductor device, one having semiconductor substrates and organic substrates laminated, is, for example, known, and more specifically, a three-dimensional layered semiconductor device is known which has such a structure that semiconductor substrates are connected to each other by e.g. electrical signal terminals such as solder bumps between the substrates, and at the same time, an interlayer filler composition is filled between the substrates so that the substrates are bonded to each other by the interlayer filler composition layer.

As a method for producing a layered semiconductor device, a process by a pre-applied process has been proposed in which on a wafer obtained by forming a semiconductor device layer, a layer made of an interlayer filler composition (ICF: Inter Chip Fill) is formed, followed by heating as the case requires for B-stage processing, then chips are cut out by dicing, whereupon a plurality of the obtained semiconductor substrates are laminated, temporary bonding by press heating is repeatedly carried out, and finally main bonding is carried out under press heating conditions (see e.g. Non-Patent Document 1).

FIGS. 1A-1D are perspective views showing a method for producing a semiconductor device by the pre-applied process, in which on a semiconductor chip 2 having a plurality of solder bumps 1 each consisting of a land terminal 1A and a solder 1B formed thereon, an interlayer filler composition 3 is supplied from an application nozzle 4 (FIG. 1A), to form an interlayer filler composition layer 5 (FIG. 1B), whereupon, as the case requires, B-stage processing is conducted, and the semiconductor chip 2 having the inter-filler composition layer 5 formed thereon is inverted, so that the interlayer filler composition layer 5 side faces on a semiconductor substrate 7 having an electrode pad 6 formed thereon, and mounted on a stage (not shown) of a thermal compression bonding apparatus, followed by pressing by a head (not shown) (FIG. 1C). Between the head and the stage of the thermal compression bonding apparatus, the semiconductor substrate 7 and the semiconductor chip 2 are heat-pressed to cure the interlayer filler composition, whereby it is possible to obtain a semiconductor device 10 having the semiconductor chip 2 and the semiconductor substrate 7 bonded via a cured adhesive layer 8 of the interlayer filler composition (FIG. 1D).

A layered semiconductor device will be produced by repeating such a process, i.e. by repeating a step in which on the semiconductor chip 2 of the semiconductor device 10 shown in FIG. 1D (in this case the electrode pad is formed on the surface opposite to the cured adhesive layer 8 of the semiconductor chip 2), the semiconductor chip 2 having the interlayer filler composition layer 5 formed thereon as shown in FIG. 1B, is further bonded.

### PRIOR ART DOCUMENT

### Non-Patent Document

Non-Patent Document 1: Lecture Proceedings by Japan Institute of Electronics Packaging (pages 61-62, 23rd, 2009)

### DISCLOSURE OF INVENTION

### Technical Problems

In the production of a semiconductor device by the pre-applied method, there are the following problems.

(1) Voids (air gaps) are formed in the cured adhesive layer. Formation of voids is considered to be caused by volatilization of e.g. low molecular weight components in the interlayer filler composition under heating conditions in the bonding step or the curing step, and if voids are present in the cured adhesive layer, not only the electrical connection will be impaired, but also the difference in shrinkage by e.g. a temperature change tends to be large, thus leading to peeling or cracking of the adhesive surface, to impair the performance as a semiconductor device.

(2) As shown in FIG. 1A, at the time of forming an interlayer filler composition layer by supplying an interlayer filler composition 3 on a semiconductor chip 2 having solder bumps 1 formed thereon, the interlayer filler composition 3 may not sufficiently be distributed in narrow spaces between the solder bumps 1,1, whereby similarly to the above (1), air gaps which become voids, will be formed, thus leading to the same problem as above.

(3) At the time of bonding between a semiconductor chip and a substrate, or between a semiconductor chip and a semiconductor chip, the interlayer filler composition may leak out from the periphery of the semiconductor chip (hereinafter referred to as “leak out of the filler”), to impair the outer appearance of the product, and besides, the leaked out portion is not involved in the bonding, and therefore the leaked out interlayer filler composition becomes waste.

For this reason, in bonding between a semiconductor chip and a substrate, or between a semiconductor chip and a semiconductor chip, it is desired to form a cured adhesive layer which is sufficiently cured and which is excellent in adhesion, without letting voids (air gaps) be formed in the cured adhesive layer and by minimizing leak out of the filler.

It is an object of the present invention to provide an interlayer filler composition for a semiconductor device which is capable of forming a cured adhesive layer sufficiently cured and excellent in adhesion without letting voids (air gaps) be formed and by minimizing leak out of the filler at the time of bonding between a semiconductor chip and a substrate, or between a semiconductor chip and a semiconductor chip in the production of a semiconductor device, and a method for producing a semiconductor device by using such an interlayer filler composition.

### Solution to Problems

The present inventors have conducted intensive studies to solve the above problems, and as a result, they have found it possible to solve the above problems and have accomplished the present invention.

That is, the present invention provides the following.

[1] An interlayer filler composition for a semiconductor device, characterized by comprising an epoxy resin (A), a curing agent (B), a filler (C) and a flux (D), having a minimum value of its viscosity at from 100 to 150° C. and satisfying the following formulae (1) and (2) simultaneously:

10<η50/η120<500 (1)

1,000<η150/η120 (2)

(wherein η50, η120 and η150 represent the viscosities at 50° C., 120° C. and 150° C., respectively, of the interlayer filler composition).
[2] The interlayer filler composition for a semiconductor device, according to the above [1], wherein its viscosity at 120° C. is from 0.1 to 100 Pa·s.
[3] The interlayer filler composition for a semiconductor device, according to the above [1] or [2], which further contains a curing accelerator (E).
[4] The interlayer filler composition for a semiconductor device, according to any one of [1] to [3], wherein the curing agent (B) is from 30 to 150 parts by weight per 100 parts by weight of the epoxy resin (A).
[5] The interlayer filler composition for a semiconductor device, according to any one of [1] to [3], wherein the curing agent (B) is within a range from 0.8 to 1.5 by an equivalent ratio of functional groups in the curing agent (B) to epoxy groups in the epoxy resin (A).
[6] The interlayer filler composition for a semiconductor device, according to any one of [1] to [5], wherein the curing agent (B) contains at least one curing agent selected from an amine-type curing agent and an acid anhydride-type curing agent.
[7] A method for producing a semiconductor device, characterized by bonding a semiconductor chip having solder bumps, and a semiconductor substrate having an electrode pad, via the interlayer filler composition as defined in any one of [1] to [6] by a thermal compression bonding apparatus.
[8] The method for producing a semiconductor device according to [7], wherein the interlayer filler composition is used in an amount of from 1 to 50 mg/cm² per area of the semiconductor chip.
[9] The method for producing a semiconductor device according to [7] or [8], wherein a layer of the interlayer filler composition is formed on the semiconductor chip having solder bumps, and the solder bumps and the electrode pad are contacted at a stage temperature of the thermal compression bonding apparatus being at least 100° C. and at a head temperature of at most 100° C.

[10] The method for producing a semiconductor device according to any one of [7] to [9], wherein at the time of bonding, the head temperature is from 200° C. to 500° C., the stage temperature is from 70° C. to 200° C., the pressing pressure is from 0.1 to 50 Kgf/cm², and the bonding time is from 0.1 to 30 seconds.

### Advantageous Effects of Invention

According to the present invention, it is possible to form a cured adhesive layer sufficiently cured and excellent in adhesion without letting voids (air gaps) be formed and by minimizing leak out of the filler at the time of bonding between a semiconductor chip and a substrate, or between a semiconductor chip and a semiconductor chip in the production of a semiconductor device, and to produce a semiconductor device excellent in reliability.

According to the present invention, it becomes possible to further increase the speed and capacity of a layered semiconductor device.

### BRIEF DESCRIPTION OF DRAWINGS

FIGS. 1A-1D are perspective views showing a method for producing a semiconductor device by a pre-applied process. FIG. 1A is a view showing an operation of applying an interlayer filler composition to a semiconductor chip. FIG. 1B is a view showing the semiconductor chip having an interlayer filler composition layer. FIG. 1C is a view showing an operation for thermal compression bonding of the semiconductor chip having the interlayer filler composition layer onto a semiconductor substrate by a thermal compression bonding apparatus (not shown). FIG. 1D is a view of a semiconductor device having the semiconductor chip and the semiconductor substrate bonded via a cured adhesive layer of the interlayer filler composition.

In FIGS. 2A and 2B, FIG. 2A is an outer photograph of a semiconductor device prepared in Example 11, and FIG. 2B is a cross-sectional photograph of the same.

### DESCRIPTION OF EMBODIMENTS

Hereinafter, the present invention will be described with reference to its embodiments, but the present invention is not limited to the following embodiments and can be practiced by modifying them in various ways within the scope of the invention.

### [Interlayer Filler Composition]

An interlayer filler composition for a semiconductor device of the present invention (hereinafter sometimes referred to also as an “interlayer filler composition”) is characterized by comprising an epoxy resin (A), a curing agent (B), a filler (C) and a flux (D), having a minimum value of its viscosity at from 100 to 150° C. and satisfying the following formulae (1) and (2) simultaneously:

10<η50/η120<500 (1)

1,000<η150/η120 (2)

wherein η50, η120 and η150 represent the viscosities at 50° C., 120° C. and 150° C., respectively, of the interlayer filler composition.

The interlayer filler composition of the present invention preferably contains a curing accelerator (E), and its viscosity at 120° C. is preferably from 0.1 to 100 Pa·s.

Here, with respect to the viscosity of the interlayer filler composition, by using a viscoelasticity measuring apparatus (Physica MCR102) manufactured by Anton Paar Japan K.K., the viscosity (the complex viscosity by dynamic viscoelasticity measurement) of the interlayer filler composition was measured as follows.

First, an interlayer filler composition to be measured was placed between a parallel plate dish and a parallel plate (Φ 20 mm), and the dynamic viscoelasticity measurement was conducted.

As the measurement conditions, 0.5% of a sine wave distortion was given to the sample, whereby the frequency of the distortion was set to be 1 (Hz), the viscosity in a process of raising the temperature at a rate of 3° C. per minute was measured from 40° C. to 200° C., and the temperature showing the minimum value of the viscosity (the minimum value temperature), the viscosity value (ηmin) being the minimum value, η50, η120 and η150 were obtained.

### [Viscosity]

### <Minimum Value>

The interlayer filler composition of the present invention shows the minimum value of its viscosity in a temperature range of from 100 to 150° C. As it shows the minimum value (ηmin) of its viscosity in this temperature range, pressing will be facilitated and bonding will be good at the time of bonding a semiconductor substrate having solder bumps, and a semiconductor substrate having an electrode pad. Preferably, the minimum value of the viscosity is preferably in a temperature range of from 110 to 140° C.

The viscosity of the interlayer filler composition of the present invention is preferably such that its minimum value is present in the above temperature range, it satisfies the above formulae (1) and (2), and the viscosity η120 at 120° C. is preferably from 0.1 to 100 Pa·s. If η120 of the interlayer filler composition is higher than 100 Pa·s, the interlayer filler composition tends to hardly flow at the time of bonding, whereby there may be a case where bonding failure occurs. Such η120 of the interlayer filler composition of the present invention is more preferably from 0.1 to 50 Pa·s, particularly preferably from 0.1 to 10 Pa·s. However, if this viscosity is excessively low, fillet formation becomes difficult, and therefore, η120 of the interlayer filler composition of the present invention is preferably at least 0.1 Pa·s.

The viscosity of the interlayer filler composition of the present invention is characterized by satisfying the above formula (1) and formula (2) at the same time. If η150/η120 is 500 or more, the viscosity at the time of the application tends to be high so that the application becomes difficult, and if it is 10 or less, the interlayer filler composition tends to hardly flow at the time of bonding, whereby formation of voids or bonding failure may be likely, or fillet formation may become difficult.

Further, particularly in the bonding of a large semiconductor chip and an organic semiconductor substrate having an electrode pad, by a difference in stress due to the difference in the respective coefficients of linear expansion, there may be cases where fracture of the semiconductor device layer, breakage of the electrical signal connecting terminals, etc. will occur.

When the formula (2) is satisfied i.e. when η150/η120 is larger than 1,000, curing of the interlayer filler composition will proceed after bonding, whereby it is possible to protect a thin semiconductor chip or semiconductor substrate. However, if this value is excessively large, there may be a case where curing proceeds before bonding, thus leading to bonding failure.

It is more preferred that the viscosity of the interlayer filler composition of the present invention satisfies, inter alia, the following formulae (1′) and (2′).

20≦η50/η120≦400 (1′)

1,100≦η150/η120 (2′)

### [Epoxy Resin (A)]

The epoxy resin (A) to be used in the present invention is, in order to improve the glass transition temperature of the interlayer filler composition of the present invention, preferably a compound having two or more epoxy groups. Further, in order to increase the fracture toughness value i.e. K1c value of a cured product obtained by heat curing the interlayer filler composition of the present invention, the range of epoxy groups contained in one molecule is preferably at least 1 and at most 8, more preferably at least 2 and at most 3.

In order to improve the thermal conductivity of the interlayer filler composition of the present invention, as the epoxy resin (A) to be used in the present invention, it is preferred to employ an epoxy compound having an aromatic ring of a bisphenol A type skeleton, a bisphenol F type skeleton or a biphenyl skeleton.

More specifically, a bisphenol A type epoxy resin, a bisphenol F type epoxy resin, a bisphenol S type epoxy resin, a biphenyl type epoxy resin, a naphthalene ring-containing epoxy resin, an epoxy resin having a dicyclopentadiene skeleton, a phenol novolak resin, a cresol novolak type epoxy resin, a triphenylmethane type epoxy resin, an aliphatic epoxy resin, a copolymer epoxy resin of an aliphatic epoxy resin and an aromatic epoxy resin, etc. may be exemplified. Among them, a bisphenol A type epoxy resins, a bisphenol F type epoxy resin, a bisphenol S type epoxy resin, a biphenyl type epoxy resin or a naphthalene ring-containing epoxy resin is preferred, and more preferably, a bisphenol A type epoxy resin, a bisphenol F type epoxy resin, a naphthalene ring-containing epoxy resin or a biphenyl type epoxy resin is used.

Further, in order to improve the fracture toughness of a cured product obtained by heat-curing the interlayer filler composition, as the epoxy resin (A) to be used in the present invention, a polyfunctional epoxy resin may also be used.

As the polyfunctional epoxy resin, preferred is a glycidyl ether-type polyfunctional epoxy resin, such as an epoxy resin to be produced from an epihalohydrin and a phenol-type compound of various types including phenols such as phenol novolac resins, cresol novolac resins, bisphenol A novolac resins, dicyclopentadiene phenolic resins, phenol aralkyl resins, naphthol novolac resins, biphenyl novolac resins, terpene phenol resins, heavy oil-modified phenolic resin phenols, etc. and polyphenol compounds obtainable by a condensation reaction of a phenol and an aldehyde such as hydroxybenzaldehyde, crotonaldehyde or glyoxal.

As the epoxy resin (A), one type may be used alone, or two or more types may be used as mixed in optional combination and ratio.

### [Curing Agent (B)]

The curing agent (B) to be used in the present invention, represents a substance contributing to the crosslinking reaction between crosslinkable groups of the epoxy resin (A).

The curing agent (B) is not particularly limited, and one which is commonly known as an epoxy resin curing agent may be used. For example, a phenolic curing agent, an amine type curing agent such as an aliphatic amine, a polyether amine, a cycloaliphatic amine or an aromatic amine, an acid anhydride type curing agent, an amide type curing agent, a tertiary amine, an imidazole or its derivative, an organic phosphine, a phosphonium salt, a tetraphenyl boron salt, an organic acid dihydrazide, a boron halide amine complex, a polymercaptan type curing agent, an isocyanate type curing agent, a blocked isocyanate curing agent, or the like, may be mentioned.

Specific examples of the phenolic curing agent include bisphenol A, bisphenol F, 4,4′-dihydroxy-diphenylmethane, 4,4′-dihydroxydiphenyl ether, 1,4-bis(4-hydroxyphenoxy) benzene, 1,3-bis(4-hydroxyphenoxy) benzene, 4,4′-dihydroxydiphenyl sulfide, 4,4′-dihydroxydiphenyl ketone, 4,4′-dihydroxydiphenyl sulfone, 4,4′-dihydroxybiphenyl, 2,2′-dihydroxybiphenyl, 10-(2,5-dihydroxyphenyl)-10H-9-oxa-10-phosphaphenanthrene-10-oxide, phenol novolac, bisphenol A novolac, o-cresol novolac, m-cresol novolac, p-cresol novolac, xylenol novolak, poly-p-hydroxystyrene, hydroquinone, resorcinol, catechol, t-butyl catechol, t-butyl hydroquinone, fluoroglucinol, pyrogallol, t-butyl pyrogallol, allylated pyrogallol, polyallylated pyrogallol, 1,2,4-benzene triol, 2,3,4-trihydroxybenzophenone, 1,2-dihydroxynaphthalene, 1,3-dihydroxynaphthalene, 1,4-dihydroxynaphthalene, 1,5-dihydroxynaphthalene, 1,6-dihydroxynaphthalene, 1,7-dihydroxynaphthalene, 1,8-dihydroxynaphthalene, 2,3-dihydroxynaphthalene, 2,4-dihydroxynaphthalene, 2,5-dihydroxynaphthalene, 2,6-dihydroxynaphthalene, 2,7-dihydroxynaphthalene, 2,8-dihydroxynaphthalene, allylated or polyallylated compounds of the above-dihydroxynaphthalenes, allylated bisphenol, allylated bisphenol F, allylated phenol novolak, allylated pyrogallol, etc.

As the amine type curing agent, the aliphatic amine may, for example, be ethylenediamine, 1,3-diaminopropane, 1,4-diaminopropane, hexamethylene diamine, 2,5-dimethyl hexamethylene diamine, trimethylhexamethylene diamine, diethylene triamine, iminobispropylamine, bis(hexamethylene) triamine, triethylene tetramine, tetraethylene pentamine, pentaethylene hexamine, N-hydroxyethyl ethylene diamine, tetra(hydroxyethyl) ethylenediamine, etc. The polyether amine may, for example, be triethylene glycol diamine, tetraethylene glycol diamine, diethylene glycol bis(propylamine), polyoxypropylene diamine, polyoxypropylene triamine, etc. The alicyclic amine may, for example, be isophoronediamine, methacenediamine, N-aminoethylpiperazine, bis(4-amino-3-methyl dicyclohexyl) methane, bis(aminomethyl) cyclohexane, 3,9-bis(3-amino propyl)-2,4,8,10-tetraoxaspiro(5,5)undecane, norbornene diamine, etc. The aromatic amine may, for example, be tetrachloro-p-xylene diamine, m-xylylenediamine, p-xylylenediamine, m-phenylenediamine, o-phenylenediamine, p-phenylenediamine, 2,4-diamino anisole, 2,4-toluenediamine, 2,4-diaminodiphenylmethane, 4,4′-diaminodiphenylmethane, 4,4′-diamino-1,2-diphenylethane, 2,4-diaminodiphenylsulfone, 4,4′-diaminodiphenylsulfone, m-aminophenol, m-amino benzylamine, benzyldimethylamine, 2-dimethylaminomethyl) phenol, triethanolamine, methylbenzylamine, α-(m-aminophenyl) ethylamine, α-(p-aminophenyl) ethylamine, diaminodiethyldimethyldiphenylmethane, α,α′-bis(4-aminophenyl)-p-diisopropylbenzene, etc. Specific examples of the acid anhydride type curing agent include dodecenyl succinic anhydride, polyadipic acid anhydride, polyazelaic acid anhydride, polysebacic acid anhydride, poly(ethyl octadecanoic diacid) anhydride, poly(phenyl hexadecanoic diacid) anhydride, methyl tetrahydrophthalic anhydride, methylhexahydrophthalic anhydride, hexahydrophthalic anhydride, methyl himic anhydride, tetrahydrophthalic anhydride, trialkyl tetrahydrophthalic anhydride, methyl cyclohexene dicarboxylic acid anhydride, methyl cyclohexene tetracarboxylic acid anhydride, phthalic anhydride, trimellitic anhydride, pyromellitic anhydride, benzophenone tetracarboxylic anhydride, ethylene glycol bistrimellitate dianhydride, HET anhydride, nadic anhydride, methyl nadic anhydride, 5-(2,5-di-oxo-tetrahydro-3-furanyl)-3-methyl-3-cyclohexane-1,2-dicarboxylic anhydride, 3,4-dimethyl-6-(2-methyl-1-propenyl)-4-cyclohexene-1,2-dicarboxylic anhydride, 3,4-dicarboxy-1,2,3,4-tetrahydro-1-naphthalene succinic dianhydride, 1-methyl-dicarboxy-1,2,3, 4-tetrahydro-1-naphthalene succinic dianhydride, etc.

The amide type curing agent may, for example, be dicyandiamide, a polyamide resin, etc.

The tertiary amine may, for example, be 1,8-diazabicyclo(5,4,0)undecene-7, triethylenediamine, benzyldimethylamine, triethanolamine, dimethylaminoethanol, tris(dimethylaminomethyl)phenol, etc.

The imidazole or its derivative may, for example, be 1-cyanoethyl-2-phenylimidazole, 2-phenylimidazole, 2-ethyl-4(5)-methyl imidazole, 2-phenyl-4-methylimidazole, 1-benzyl-2-methylimidazole, 1-benzyl-2-phenylimidazole, 1-cyanoethyl-2-undecylimidazole, 1-cyano-2-phenyl imidazole, 1-cyanoethyl-2-undecylimidazole trimellitate, 1-cyanoethyl-2-phenylimidazolium trimellitate, 2,4-diamino-6-[2′-methyl imidazolyl-(1′)]-ethyl-s-triazine, 2,4-diamino-6-[2′-ethyl-4′-methyl imidazolyl-(1′)]ethyl-s-triazine, 2,4-diamino-6-[2′-methyl-imidazolyl-(1′)]ethyl-s-triazine isocyanuric acid adduct, 2-phenylimidazole isocyanuric acid adduct, 2-phenyl-4,5-dihydroxy methyl imidazole, 2-phenyl-4-methyl-5-hydroxymethyl-imidazole, an adduct of an epoxy resin and the above-mentioned imidazole, etc.

The organic phosphine may, for example, be tri-butyl phosphine, methyl diphenyl phosphine, triphenyl phosphine, diphenyl phosphine, phenyl phosphine, etc.; and the phosphonium salt may, for example, be tetraphenylphosphonium-tetraphenyl borate, tetraphenylphosphonium-ethyl triphenyl borate, tetrabutylphosphonium-tetrabutyl borate, etc. The tetraphenyl boron salt may, for example, be 2-ethyl-4-methylimidazole-tetraphenyl borate, N-methylmorpholine-tetraphenyl borate, etc.

As the curing agent (B), one type may be used alone, or two or more types may be used as mixed in optional combination and ratio.

The content of the curing agent (B) in the interlayer filler composition of the present invention is preferably from 30 to 150 parts by weight, more preferably from 50 to 120 parts by weight, per 100 parts by weight of the epoxy resin (A).

Further, in a case where the curing agent (B) is a phenol type curing agent, an amine type curing agent or an acid anhydride type curing agent, it is preferably used to be in a range of from 0.8 to 1.5, more preferably used to be in a range of from 0.8 to 1.2, by an equivalent ratio of functional groups in the curing agent (B) to epoxy groups in the epoxy resin (A). Outside this range, unreacted epoxy groups or functional groups of the curing agent may remain, and the desired physical properties may not be obtainable.

Further, in a case where the curing agent (B) is an amide type curing agent, a tertiary amine, imidazole or its derivative, an organic phosphine, a phosphonium salt, a tetraphenyl boron salt, an organic acid dihydrazide, a boron halide amine complex, a polymercaptan-type curing agent, an isocyanate curing agent or a block isocyanate curing agent, it is preferably used to be in a range of from 0.1 to 20 parts by weight, more preferable used to be in a range of from 0.5 to 10 parts by weight, per 100 parts by weight of the epoxy resin (A).

Further, in the case of a dicyandiamide compound, it is preferably used to be in a range of from 0.1 to 10 parts by weight, more preferably to be in a range of from 0.5 to 6 30 parts by weight, per 100 parts by weight of the epoxy resin (A).

### [Filler (C)]

The filler (C) is one to be added for the purpose of improving the thermal conductivity and controlling the linear expansion coefficient, and particularly the control of the linear expansion coefficient is the main objective.

As the filler (C), at least one type of particles selected from the group consisting of metal, carbon, metal carbide, a metal oxide and a metal nitride may be mentioned.

Examples of carbon include carbon black, carbon fiber, graphite, fullerene, diamond, etc. Examples of the metal carbide include silicon carbide, titanium carbide, tungsten carbide, etc. Examples of the metal oxide include magnesium oxide, aluminum oxide, silicon oxide, calcium oxide, zinc oxide, yttrium oxide, zirconium oxide, cerium oxide, ytterbium oxide, sialon (ceramic consisting of silicon, aluminum, oxygen and nitrogen), etc. Examples of the metal nitride include boron nitride, aluminum nitride, silicon nitride, etc.

There is no limitation with respect to the shape of the filler (C), and it may be particulates, whiskers, fibers, plates, or aggregates thereof. For the interlayer filler composition for a layered semiconductor device, the insulating property is required in many cases, and therefore, as the filler (C), an oxide or nitride is preferred. Such filler (C) may, more specifically, be alumina (Al₂O₃), aluminum nitride (AlN), boron nitride (BN), silicon nitride (Si₃N₄), silica (SiO₂), etc. Among them, Al₂O₃, AlN, BN or SiO₂ is preferred, and Al₂O₃, BN or SiO₂ is particularly preferred.

As the BN-type filler, one disclosed in JP-A-2013-241321 is preferably used.

As the filler (C), one type may be used alone, or two or more types may be used as mixed in optional combination and ratio.

In recent years, in a three-dimensional integrated circuit, in order to improve the performance for e.g. higher speed and higher capacity, the distance between the respective chips has been reduced to a level of from about 10 to 50 μm, and in an interlayer filling layer between the chips, the maximum particle size of the filler to be incorporated, is preferably made to be at a level of at most ⅓ of the thickness of the interlayer filling layer.

If the maximum particle size of the filler (C) exceeds 10 μm, the filler (C) tends to protrude on the surface of the interlayer filling layer after being cured, thereby to deteriorate the surface shape of the interlayer filling layer.

The maximum particle size of the filler (C) is preferably 5 μm, more preferably 3 μm.

The content of the filler (C) in the interlayer filler composition of the present invention is preferably from 10 to 500 parts by weight, more preferably from 20 to 400 parts by weight, per 100 parts by weight in total of the epoxy resin (A) and the curing agent (B). If the content of the filler (C) is less than 10 parts by weight per 100 parts by weight in total of the epoxy resin (A) and the curing agent (B), the effect of adding the filler (C) tends to be small, and there may be a case where the intended linear expansion coefficient or thermal conductivity is not obtainable, and if it exceeds 500 parts by weight, the presence of the filler (C) may sometimes impair bonding properties.

### [Flux (D)]

The flux (D) is, specifically, a compound having a function of e.g. dissolving and removing a surface oxide film of a land and metal electrical signal terminals of e.g. solder bumps, etc., or improving wet spreadability on the land surface of the solder bumps, or preventing re-oxidation of metal electrical terminal surface of the solder bumps, at the time of solder bonding of the metal terminals.

The flux (D) to be used in the present invention may, for example, be an aliphatic carboxylic acid such as oxalic acid, malonic acid, succinic acid, glutaric acid, adipic acid, malic acid, tartaric acid, citric acid, lactic acid, acetic acid, propionic acid, butyric acid, oleic acid, stearic acid, etc.; an aromatic carboxylic acid or its acid anhydride, such as benzoic acid, salicylic acid, phthalic acid, trimellitic acid, trimellitic anhydride, trimesic acid, benzene tetracarboxylic acid, etc.; an organic carboxylic acid such as abietic acid, a terpene-type carboxylic acid such as rosin; an organic carboxylic acid ester being a hemiacetal ester having an organic carboxylic acid reacted with and converted by an alkyl vinyl ether; an organic halogen compound such as glutamic acid hydrochloride, aniline hydrochloride, hydrazine hydrochloride, cetyl bromide pyridine, phenyl hydrazine hydrochloride, tetra-chloronaphthalene, methyl hydrazine hydrochloride, methylamine hydrochloride, ethylamine hydrochloride, diethylamine hydrochloride, butylamine hydrochloride, etc.; an amine such as urea, diethylenetriamine hydrazine, etc.; a polyhydric alcohol such as ethylene glycol, diethylene glycol, triethylene glycol, tetraethylene glycol, glycerin, etc.; an inorganic acid such as hydrochloric acid, hydrofluoric acid, phosphoric acid, fluoroboric acid, etc.; a fluoride such as potassium fluoride, sodium fluoride, ammonium fluoride, copper fluoride, nickel fluoride, zinc fluoride, etc.; a chloride such as potassium chloride, sodium chloride, cuprous chloride, nickel chloride, ammonium chloride, zinc chloride, stannous chloride, etc.; a bromide such as potassium bromide, sodium bromide, ammonium bromide, tin bromide, zinc bromide, etc.; etc. These compounds may be used as they are, or may be used as microencapsulated with a coating agent of e.g. an organic polymer or inorganic compound. One of these compounds may be used alone, or two or more of them may be used as mixed in optional combination and ratio.

The content of the flux (D) in the interlayer filler composition of the present invention is preferably from 0.1 to 10 parts by weight, more preferably from 0.5 to 5 parts by weight, per 100 parts by weight in total of the epoxy resin (A) and the curing agent (B). If the content of the flux (D) is less than 0.1 part by weight per 100 parts by weight in total of the epoxy resin (A) and the curing agent (B), there is a danger of solder connection failure due to a decrease in oxide film removability, and if it exceeds 10 parts by weight, there will be a possible danger of connection failure due to an increase in the viscosity of the composition.

### [Curing Accelerator (E)]

The interlayer filler composition of the present invention may contain a curing accelerator (E) together with the curing agent (B) in order to lower the curing temperature or to shorten the curing time.

Examples of the curing accelerator (E) include a compound containing a tertiary amino group, imidazole or its derivative, an organic phosphine, dimethylurea, and one having the above compound microencapsulated by using a coating agent of e.g. an organic polymer or an inorganic compound.

The compound containing a tertiary amino group may, for example, be 1,8-diazabicyclo(5,4,0)undecene-7, triethylenediamine, benzyldimethylamine, triethanolamine, dimethylaminoethanol, tris(dimethylaminomethyl)phenol, etc. The imidazole or its derivative may, for example, be 1-cyanoethyl-2-phenylimidazole, 2-phenylimidazole, 2-ethyl-4(5)-methyl imidazole, 2-phenyl-4-methylimidaxole, methylimidazole, 1-benzyl-2-methylimidazole, 1-benzyl-2-phenylimidazole, 1-cyanoethyl-2-undecylimidazole, 1-cyano-2-phenyl imidazole, 1-cyanoethyl-2-undecylimidazole trimellitate, 1-cyanoethyl-2-phenyl-imidazolium trimellitate, 2,4-diamino-6-[2′-methyl imidazolyl-(1′)] ethyl-s-triazine, 2,4-diamino-6-[2′-ethyl-4′-methyl imidazolyl-(1′)]ethyl-s-triazine, 2,4-diamino-6-[2′-methyl-imidazolyl-(1′)]-ethyl-s-triazine isocyanuric acid adduct, 2-phenylimidazole isocyanuric acid adduct, 2-phenyl-4,5-dihydroxy methyl imidazole, 2-phenyl-4-methyl-5-hydroxymethyl-imidazole, an adduct of an epoxy resin and the above imidazole, 2-phenyl-4,5-dihydroxy methylimidazole, 2-phenyl-4-methyl-5-hydroxymethyl imidazole, etc.

The organic phosphine may, for example, be tributyl phosphine, methyl diphenyl phosphine, triphenylphosphine, diphenylphosphine, phenylphosphine, etc. The phosphonium salt may, for example, be tetraphenylphosphonium-tetraphenyl borate, tetraphenylphosphonium-ethyl triphenyl borate, tetrabutylphosphonium-tetrabutyl borate, etc. The tetraphenyl boron salt may, for example, be 2-ethyl-4-methylimidazole-tetraphenyl borate, N-methylmorpholine-tetraphenyl borate, etc.

Among these, it is preferred to use an imidazole compound (imidazole or its derivative) or one having the above compound microencapsulated by using an organic polymer and inorganic compound, from the viewpoint of characteristics such as a relatively long pot life, high curability in an intermediate temperature range, high heat resistance of the cured resin, etc.

As the curing accelerator (E), one type may be used alone, or two or more types may be used as mixed in optional combination and ratio.

In a case where the curing accelerator (E) is to be contained in the interlayer filler composition of the present invention, the content of the curing accelerator (E) is preferably from 0.001 to 15 parts by weight, more preferably from 0.01 to 10 parts by weight, per 100 parts by weight in total of the epoxy resin (A) and the curing agent (B). If the content of the curing accelerator (E) is less than 0.001 part by weight per 100 parts by weight in total of the epoxy resin (A) and the curing agent (B), there is a possibility that the curing acceleration effect may become insufficient, and if it exceeds 15 parts by weight, the catalytic curing reaction tends to be dominant, whereby there may be a case where reduction of voids cannot be achieved.

### [Dispersant(F)]

The interlayer filler composition of the present invention preferably contains a dispersant (F) in order to improve the dispersibility of the filler (C). The dispersant (F) is not particularly limited, and it is possible to use any one known as a dispersant to be incorporated heretofore to an interlayer filler composition.

In the interlayer filler composition of the present invention, the content of the dispersant (F) may be at any level so long as it is one capable of solving the problem of the present invention, but the dispersant (F) is preferably from 0.1 to 4 parts by weight, more preferably from 0.1 to 2 parts by weight, per 100 parts by weight of the above filler (C).

### [Other Additives]

The interlayer filler composition of the present invention may contain various additives other than those mentioned above for the purpose of further improving the functionality in a range of not impairing the effects of the present invention.

Examples of the additives include a coupling agent for improving the bonding property or the bonding property of the epoxy resin (A) and the filler (C), a UV shielding agent for improving storage stability, an antioxidant, a plasticizer, a flame retardant, a colorant, a flow improver, an agent to improve adhesion with a substrate (e.g. a thermoplastic oligomer), etc.

Such other additives may each be used singly, or two or more of them may be used as mixed in optional combination and ratio.

The blend amount of such other additives is not particularly limited, and they may be used in a blend amount in a usual resin composition to such an extent that necessary functionality is obtainable, but the blend amount of other additive components is preferably at most 10 parts by weight, particularly preferably at most 5 parts by weight, per 100 parts by weight in total of the epoxy resin (A) and the curing agent (B).

The above coupling agent may, for example, be a silane coupling agent, a titanate coupling agent, etc.

The silane coupling agent may, for example, be an epoxysilane such as γ-glycidoxypropyltrimethoxysilane, γ-glycidoxypropyl triethoxy silane, β-(3,4-epoxycyclohexyl) ethyl trimethoxysilane, etc.; an aminosilane such as γ-aminopropyl triethoxysilane, N-β (aminoethyl) γ-aminopropyltrimethoxysilane, N-β (aminoethyl) γ-aminopropyl methyl dimethoxy silane, γ-aminopropyltrimethoxysilane, γ-ureidopropyltriethoxysilane, etc.; a mercapto silane such as 3-mercaptopropyl trimethoxysilane; a vinyl silane such as p-styryl trimethoxysilane, vinyl trichlorosilane, vinyl tris(β-methoxyethoxy) silane, vinyltrimethoxysilane, vinyltriethoxysilane, γ-methacryloxypropyl vinylsilane, etc.; and further, a polymer type silane of epoxy-type, amino-type or vinyl-type; etc.

The titanate coupling agent may, for example, be isopropyl triisostearoyl titanate, isopropyl tri(N-aminoethyl-aminoethyl) titanate, diisopropyl bis(dioctyl phosphate) titanate, tetraisopropyl bis(dioctyl phosphite) titanate, tetra-octyl bis(ditridecyl phosphite) titanate, tetra(2,2-diallyl oxymethyl-1-butyl) bis(ditridecyl) phosphite titanate, bis(dioctyl pyrophosphate) oxyacetate titanate, bis(dioctyl pyrophosphate)ethylene titanate, etc.

One of these coupling agents may be used alone, or two or more of them may be used as mixed in optional combination and ratio.

In a case where the interlayer filler composition of the present invention contains a coupling agent, its content is preferably from about 0.1 to 2.0 wt % based on the total solid content in the interlayer filler composition. If the blend amount of the coupling agent is small, it will not be possible to sufficiently obtain the effect to improve the adhesion between the epoxy resin (A) being the matrix resin, and the filler (C), by the blending of the coupling agent, and if it is too much, there will be such a problem that the coupling agent may bleed out from the cured product obtained.

The interlayer filler composition of the present invention may contain a thermoplastic oligomer in order to improve flowability at the time of molding and to improve adhesion with the substrate. The thermoplastic oligomer may, for example, be a C5-type or C9-type petroleum resin, a styrene resin, an indene resin, an indene-styrene copolymer resin, an indene-styrene-phenol copolymer resin, an indene-coumarone copolymer resin, an indene-benzothiophene copolymer resin, etc. One of these may be used alone, or two or more of them may be used as mixed.

In a case where the interlayer filler composition of the present invention contains such a thermoplastic oligomer, its content is usually from 2 to 30 parts by weight, preferably from 5 to 20 parts by weight, per 100 parts by weight of the epoxy resin (A).

The interlayer filler composition of the present invention may further contain a surfactant, an emulsifier, an elasticity-reducing agent, a diluent, a defoamer, an ion trapping agent, etc.

As the surfactant, any of conventional anionic surfactants, nonionic surfactants and cationic surfactants may be used.

For example, polyoxyethylene alkyl ethers, polyoxyethylene alkyl aryl ethers, polyoxyethylene alkyl esters, sorbitan alkyl esters, monoglyceride alkyl esters, alkylbenzenesulfonic acid salts, alkylnaphthalene sulfonic acid salts, alkyl sulfates, alkyl sulfonic acid salts, sulfosuccinic acid ester salts, alkyl betaines, amino acids, etc., may be mentioned.

Further, a fluorinated surfactant having some or all of C—H bonds in such a surfactant converted to C—F bonds may also be preferably used.

In a case where the interlayer filler composition of the present invention contains such a surfactant, its content is usually within a range of from 0.001 to 0.1 part by weight, preferably from 0.003 to 0.05 part by weight, per 100 parts by weight in total of the epoxy resin (A) and the curing agent (B).

Further, an organic solvent may be added to the interlayer filler composition of the present invention.

The organic solvent may, for example, be a ketone such as acetone, methyl ethyl ketone (MEK), methyl isobutyl ketone, methyl amyl ketone, cyclohexanone, etc.; an ester such as ethyl acetate; an ether such as ethylene glycol monomethyl ether; an amide such as N,N-dimethylformamide, N, N-dimethylacetamide, etc.; an alcohol such as methanol, ethanol, etc.; an alkane such as hexane, cyclohexane, etc.; an aromatic compound such as toluene, xylene, etc.

Among these, in consideration of the solubility of the resin and the boiling point of the organic solvent, a ketone such as methyl ethyl ketone or cyclohexanone, an ester, or an ether, is preferred, and it is particularly preferred to use a ketone such as methyl ethyl ketone or cyclohexanone.

One of these organic solvents may be used alone, or two or more of them may be used as mixed in optional combination and ratio.

However, if an organic solvent is used, since the organic solvent is likely to volatilize in the bonding step, voids are likely to be formed in the cured adhesive layer, and therefore, the interlayer filler composition of the present invention preferably contains no organic solvent.

### [Method for Producing Interlayer Filler Composition]

The interlayer filler composition of the present invention is usually produced by uniformly mixing the epoxy resin (A), the curing agent (B), the filler (C), the flux (D), and to be used as the case requires, the curing accelerator (E), the dispersant (F) and other additive components, by e.g. a mixer, followed by kneading by e.g. a heating roll, a kneader or the like. There is no particular limitation to the order of blending these components. It is also possible to form a film by using a pressing machine after kneading. Furthermore, it is possible to pulverize the melt-kneaded product after kneading, for powdering or tableting.

### [Method for Producing Semiconductor Device]

Hereinafter, a method for producing a semiconductor device of the present invention using the interlayer filler composition of the present invention, will be described.

In the method for producing a semiconductor device of the present invention, by using a thermal compression bonding apparatus, a semiconductor chip having solder bumps and a semiconductor substrate having an electrode pad are heat-pressed and bonded via the above-described interlayer filler composition of the present invention.

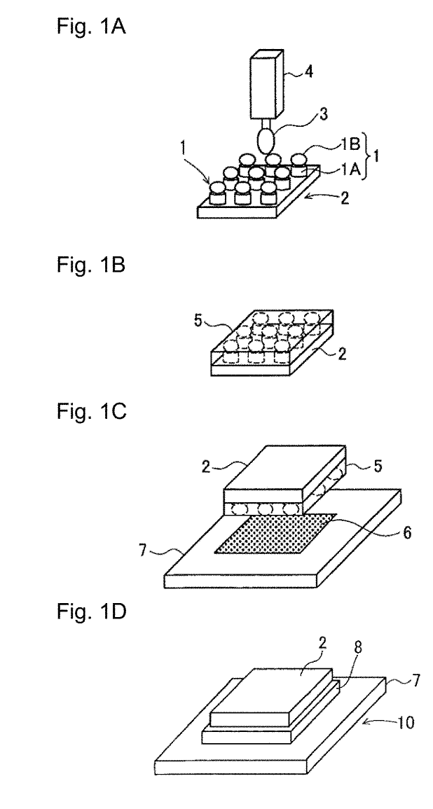

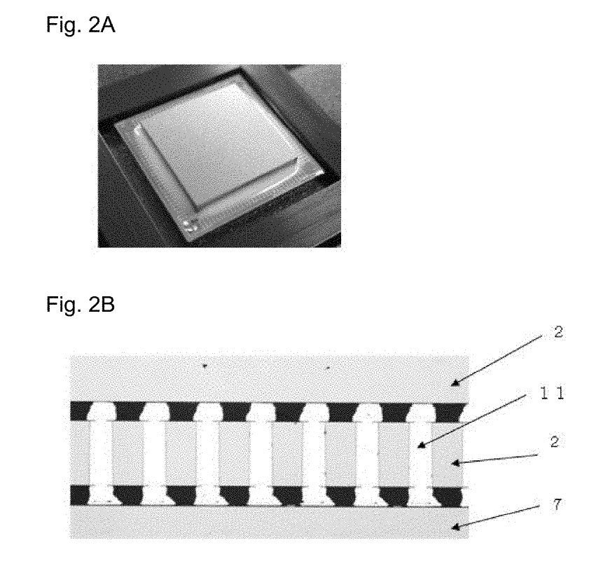

For example, as shown in FIG. 1A, on a semiconductor substrate (semiconductor chip) 2 having formed thereon a plurality of solder bumps 1 each consisting of a land terminal 1A and solder 1B, the interlayer filler composition 3 of the present invention is supplied from an application nozzle 4, to form an interlayer filler composition layer 5, as shown in FIG. 1B, followed by B stage processing, as the case requires. Thereafter, the semiconductor chip 2 having the interlayer filler composition layer 5 formed thereon is vertically inverted and, as shown in FIG. 1C, pressed by a head not shown, on a semiconductor substrate 7 having an electrode pad 6 formed thereon and mounted on the stage (not shown) of a thermal compression bonding apparatus, so as to let the interlayer filler composition layer 5 side face the substrate 7. By heating and pressing the semiconductor substrate 7 and the semiconductor chip 2 between the head and the stage of the thermal compression bonding apparatus, the interlayer filler composition is cured to obtain, as shown in FIG. 1D, a semiconductor device 10 having the semiconductor chip 2 and the semiconductor substrate 7 bonded via a cured adhesive layer 8 of the interlayer filler composition.

A layered semiconductor device can be prepared by repeating such a process, i.e. by repeating a step of bonding the semiconductor chip 2 having the interlayer filler composition layer 5 formed thereon as shown in FIG. 1B further on the semiconductor chip 2 of the semiconductor device 10 shown in FIG. 1D (in this case an electrode pad is formed on the surface opposite to the cured adhesive layer 8 of the semiconductor chip 2).

As the semiconductor substrate in the present invention, it is possible to use any optional material which can be used as a substrate in the fabrication of integrated circuits, but a silicon substrate is preferably used. As the silicon substrate, one having a desired thickness may be used as it is, or it may be used after thinning to 100 μm or less by back surface grinding such as back-side etching or back grinding.

For the formation of solder bumps, fine solder balls may be used, or after forming openings by lithography, solder plating is applied directly on underlying openings, or after forming nickel or copper posts, and after removal of a resist material, heat treatment may be conducted to form solder bumps. No particular limitation is imposed to the composition of solder, but in consideration of electrical bonding property and low-temperature bonding property, solder containing tin as the major component is preferably used.

Land terminals may be formed by forming a thin film on a semiconductor substrate by using e.g. PVD (Physical Vapor Deposition), followed by a resist film formation by lithography, and dry or wet etching to remove unnecessary portions. The material for the land terminals is not particularly limited so long as it can be bonded to the solder bumps, but in consideration of bonding property to solder and reliability, gold, copper, nickel or the like may be preferably used.

The interlayer filler composition layer by a pre-applied process may be formed by a conventional forming method, for example, a dipping method, a spin coating method, a spray coating method, a blade method or any other optional method. The interlayer filler composition layer may be applied to either side of a semiconductor chip having solder bumps, or a semiconductor substrate having an electrode pad, or may be applied to both sides, but it is preferably formed on the surface having solder bumps of the semiconductor chip.

The supply amount of the interlayer filler composition to the semiconductor chip, is preferably from 1 to 50 mg/cm², particularly preferably from 2 to 30 mg/cm², per area of the semiconductor chip. Also in the case of supplying the interlayer filler composition to the semiconductor substrate side, or in the case of supplying the interlayer filler composition on both the semiconductor chip and the semiconductor substrate to form an interlayer filler composition layer, the interlayer filler composition may be applied so that the supply amount would be the same level.

After forming the interlayer filler composition layer on the semiconductor chip (and/or the semiconductor substrate), in order to remove low molecular weight components, etc. contained in the interlayer filler composition, baking treatment may be conducted at an optional temperature of from 50 to 150° C., preferably at an optional temperature of from 60 to 130° C., to conduct a B-stage processing.

At that time, the baking treatment may be conducted at a constant temperature, but, in order to facilitate removal of volatile components in the composition, the baking treatment may be conducted under a reduced pressure condition. Furthermore, to such an extent that curing of the resin does not proceed, the baking treatment may be carried out by raising the temperature stepwise. For example, the baking treatment may be carried out firstly at 60° C., then at 80° C. and further at 120° C. each for about 5 to 90 minutes.

After forming the interlayer filler composition layer, temporary bonding to a substrate may be carried out. The temperature for the temporary bonding is preferably at a level of from 80 to 150° C. In a case where bonding of semiconductor substrates is for a plurality of layers, said temporary bonding may be repeated a number of times corresponding to the plurality of layers, or substrates are overlaid one another in a plurality of layers and then heated to be collectively temporarily bonded. At the time of temporary bonding, as the case requires, it is preferred to exert a load of preferably from 1 gf/cm² to 50 Kgf/cm², more preferably from 10 gf/cm² to 10 Kgf/cm², between the substrates.

After forming the interlayer filler composition layer, bonding is carried out. In a case where the above temporary bonding has been carried out, the main bonding is carried out subsequently, and in such a case, the “bonding” in the present invention is meant for heat press bonding to be carried out by this main bonding. In some cases, temporarily bonded layered substrates may be press-bonded at a temperature of at least 200° C., preferably at least 220° C., to lower the melt viscosity of the composition contained in the interlayer filler layer, to facilitate connection of the electrical terminals between substrates and at the same time to realize solder bonding between the semiconductor substrates. The upper limit of the heating temperature may be suitably determined so long as it is a temperature at which the epoxy compound (A) used would not be decomposed or modified, but it is usually at most 300° C. In such a case, the temperature of the head of the thermal compression bonding apparatus is preferably from 200° C. to 500° C., more preferably from 250° C. to 450° C. Further, the temperature of the stage is preferably from 70° C. to 200° C., more preferably from 100° C. to 150° C. Further, as the case requires, it is preferred to carry out the heat bonding by applying a load of preferably from 0.1 to 50 Kgf/cm², more preferably from 0.1 to 10 Kgf/cm², between the substrates. The heating and pressing time is preferably from 0.1 to 30 seconds, more preferably from 0.5 to 10 seconds, particularly preferably from 3 to 10 seconds.

In the process for producing a semiconductor device having a step of bonding a semiconductor chip having solder bumps, and a semiconductor substrate having an electrode pad, via an interlayer filler composition by using a thermal compression bonding apparatus, as described above, bonding conditions of various steps at the stage before boding are also independently important to produce a high-quality semiconductor device. Of course, it is possible to produce a particularly high-quality semiconductor device in a case where conditions of the step of bonding by using the thermal compression bonding apparatus, and conditions of various steps at the stage before bonding, are both preferred conditions.

In a step at the stage before the heat press bonding, the solder bumps and the electrode pad are brought in contact with each other, and at the time of such contact, it is preferred to contact the solder bumps and the electrode pad by pressing them at a stage temperature of the thermo-compression bonding apparatus being at least 100° C. and at a head temperature of at least 100° C. It is preferred to conduct the heat press bonding after this contact. Usually, a layer of the interlayer filler composition is preliminarily formed on a semiconductor chip having solder bumps.

Preparation of a semiconductor device of the present invention can be carried out via a bonding step under such temperature conditions. By carrying out bonding by means of the thermal compression bonding apparatus under such temperature conditions by using the interlayer filler composition of the present invention having the above-mentioned viscosity characteristics, it is possible to prevent an increase in the viscosity due to the curing of the interlayer filler composition before the heat press bonding and to prevent formation of voids, thereby to accomplish good connection. Further, by controlling η150/η120 of the interlayer filler composition of the present invention, it is possible to prevent leak out of the filler, and further, by controlling η150/η120 of the interlayer filler composition of the present invention, it is possible to sufficiently cure the interlayer filler composition, thereby to form a cured adhesive layer excellent in adhesion.

Here, the head temperature is the temperature of a heater of the head of the thermal compression bonding apparatus, and the stage temperature is the temperature of a heater of the stage of the thermal compression bonding apparatus.

In the step of contacting the solder bumps and the electrode pad before heat press bonding, if the stage temperature is less than 100° C., it becomes necessary to increase the head temperature at the time of heat press bonding, whereby voids tend to be formed, and if the head temperature exceeds 100° C., the progression of curing of the interlayer filler composition becomes too fast. Further, even if the stage temperature is at least 100° C., if the head temperature exceeds 100° C., the progress in curing of the interlayer filler composition tends to be too fast, and even if the head temperature is at most 100° C., if the stage temperature is less than 100° C., it is necessary to increase the head temperature at the time of heat press bonding, and voids tend to be formed.

However, if the stage temperature is too high, the interlayer filler composition tends to be cured at the time of pressing the semiconductor chip having solder bumps and the semiconductor substrate having an electrode pad, and therefore, the stage temperature is preferably at most 200° C.

Further, if the head temperature is too low, the viscosity of the interlayer filler composition tends to be high at the time of pressing the semiconductor chip having solder bumps and the semiconductor substrate having an electrode pad, and the solder bumps and the electrode pad tend to be less likely to contact, and therefore, the head temperature is preferably at least 40° C.

The stage temperature is preferably from 100 to 200° C., more preferably from 100 10 to 160° C., particularly preferably from 100 to 150° C., and the head temperature is preferably from 40 to 100° C., particularly preferably from 60 to 100° C.

### EXAMPLES

Hereinafter, the present invention will be described more specifically with reference to Examples and Comparative Examples, but the present invention is not limited in any way by the following Examples, so long as it does not exceed the gist of the present invention.

In the following, blend components used for preparing the interlayer filler composition are as follows.

### <Epoxy Resin (A)>

Epoxy resin (A1): manufactured by Daiso Chemical Co., Ltd., product name “LX-01” (bisphenol A type glycidyl ether epoxy resin, epoxy equivalent 181 g/eq, viscosity at 25° C. 10 Pa·s)

Epoxy resin (A2): manufactured by Mitsubishi Chemical Corporation, product name “jER 1032H60” (tris(hydroxyphenyl) methane type solid epoxy resin, epoxy equivalent 169g/eq., melting point 56 to 62° C.)

### <Curing Agent (B)>

Acid anhydride-type curing agent (B1): manufactured by Mitsubishi Chemical Corporation, product name “jER cure YH306” (3,4-dimethyl-6-(2-methyl-1-propenyl)-4-cyclohexene-1,2-dicarboxylic acid anhydride, an acid anhydride equivalent 117 g/eq, viscosity at 25° C. 0.1 Pa·s)

Amine curing agent (B2): manufactured by Ihara Chemical Industry Co., Ltd., product name “ELASMER 250P” (polytetramethyleneoxy bis-4-amino benzoate, an amine value of 235 g/eq., melting point 60° C., viscosity at 25° C. 100 Pa·s)

Amine curing agent (B3): manufactured by Wakayama Seika Kogyo Co., Ltd., product name “SEIKACURE-S” (amine value 124 gleq., melting point 177° C.)

### <Filler (C)>

Inorganic filler (C1): manufactured by Sumitomo Chemical Co., Ltd., product name “AA-3” (alumina)

Inorganic filler (C2): manufactured by Sumitomo Chemical Co., Ltd., product name “AA-07” (alumina)

Inorganic filler (C3): manufactured by Tatsumori, product name “PLV-4” (fused silica)

Inorganic filler (C4): manufactured by Tatsumori, product name “MUF-2BV” (fused silica)

Inorganic filler (C5): manufactured by Nissin Refratech Co., Ltd., product name “RBN” (boron nitride)

Inorganic filler (C6): manufactured by Admatechs Company Limited, product name “SE-4050-SEC” (fused silica)

Inorganic filler (C7): manufactured by Admatechs Company Limited, product name “AE9104-SXE” (alumina)

Inorganic filler (C8): manufactured by Tatsumori, product name “TS-AP-9” (alumina)

### <Flux (D)>

Flux (D1): manufactured by NOF Corporation, product name “Suntacid I” (mono alkyl vinyl ether block bifunctional carboxylic acid)

Flux (D2): manufactured by Wako Pure Chemical Industries, Ltd., product name “adipic acid”

Flux (D3): manufactured by Wako Pure Chemical Industries, Ltd., product name “pimelic acid”

Flux (D4): manufactured by Wako Pure Chemical Industries, Ltd., product name “glutaric acid”

Flux (D5): manufactured by NOF Corporation, product name “ Suntacid G” (dialkyl ether block 2 functional polymer type carboxylic acid)

### <Curing Accelerator (E)>

Curing accelerator (E1): manufactured by Asahi Kasei E-Materials Corp., product name “Novacure HXA3792” (a mixture of microencapsulated amine-type curing agent and a bisphenol A type liquid epoxy resin)

Voids and bonding properties (evaluation by electric resistance) of the interlayer filler composition were evaluated by the following methods.

### (1) Voids

With respect to a produced semiconductor device, using a ultrasonic inspection imaging device (FS300III) manufactured by Hitachi Power Solutions Co., Ltd., the presence or absence of voids between a bump and a bump between bonded chips was observed. A case where voids were at most 10 was evaluated to be “o”, and a case where voids were more than 11 was evaluated to be “x”.

### (2) Bonding Properties (Resistance Value)

### 1. In the Case of Si—Si Bonding

The electrical resistance of the daisy chain inside of the produced semiconductor device was measured by a four-terminal method by a digital multimeter. A case where it was within ±5% to the outer circumferential resistance value R1=70Ω and to the inner circumferential resistance value R2=27Ω of the peripheral portion, was evaluated to be “o”, and a case where it exceeded ±5% was evaluated to be “x”.

### 2. In the Case of Si-Organic Substrate Bonding

The electrical resistance of the daisy chain inside of the produced semiconductor device was measured by a four-terminal method by a digital multimeter. A case where it was within ±5% to the outer circumferential resistance value R1=15Ω of the outer peripheral portion was evaluated to be “o”, and a case where it exceeded ±5% was evaluated to be “x”.

### Examples 1 to 10, Comparative Examples 1 to 4

The blend components of the interlayer filler composition shown in Table 1, were mixed in a blend weight ratio shown in Table 1 by a rotation revolution mixer to prepare an interlayer filler composition.

With respect to the prepared interlayer filler composition, the temperature showing the minimum value of the viscosity (the minimum value temperature), the viscosity value (ηmin) being the minimum value, η50, η120, and η150 were measured, respectively, and the results are shown in Table 2.

### 1. In the Case of Si—Si Bonding

As shown in Table 3, the prepared interlayer filler composition was applied to an interposer (IP80Modell, 10 mm square) manufactured by WALTS or to a silicon solder bump substrate (CC80Modell, 7.3 mm square), in an amount of about 10 mg while heating at 70° C.

By placing the interposer (IP80Modell) at the stage side, and the silicon solder bump substrate (CC80Modell, 7.3 mm square) at the head side, by means of a thermal compression bonding apparatus “Flip chip bonder (FC3000S)” manufactured by Toray Engineering Co., Ltd., bonding was carried out at the head temperature and stage temperature at the time when the interposer and the silicon solder bump substrate were in contact, and the head temperature, stage temperature and pressing pressure at the time of bonding, as shown in Table 3.

### 2. In the Case of Si-Organic Substrate Bonding

As shown in Table 3, the prepared interlayer filler composition was applied to KIT (CC80-103SY Modell) or to a silicon solder bump substrate (CC80Modell, 7.3 mm square), in an amount of about 10 mg while heating at 70° C.

By placing the organic substrate KIT (CC80-103JY Modell, 17 mm square) at the stage side and the silicon solder bump substrate (CC80Modell, 7.3 mm square) at the head side, by means of a thermal compression bonding apparatus “Flip-chip bonder (FC3000S)” manufactured by Toray Engineering Co., Ltd., bonding was carried out at the head temperature and stage temperature at the time when KIT and the silicon solder bump substrate were in contact, and at the head temperature, stage temperature and pressing pressure at the time of bonding, as shown in Table 3.

### (1) Evaluation of Voids, and (2) Evaluation of Bonding Properties

With respect to the semiconductor devices obtained by the above 1 Si—Si bonding and by the above 2. Si-organic substrate bonding, the above-mentioned evaluations were carried out, and the results are shown in Table 3.

### (3) Evaluation of Curability

With the prepared interlayer-filler composition, at the time of the above 1. Si—Si bonding and 2. Si-organic substrate bonding, the interposer and KIT were, respectively, turned over and bonded under the conditions as shown in Table 3, in the same manner as described above. A case where the silicon solder bump substrate of the obtained semiconductor device was not peeled by pressing from the side was evaluated to be o, and a case where it was peeled, was evaluated to be x. The results are shown in Table 3.

### Example 11

The interlayer filler composition used in Example 4 was applied to an interposer, (CC80Modell, 10 mm square) manufactured by WALTS Co., Ltd. in an amount of about 3 mg (about 6 mg/cm2 per effective area) while heating at 70° C.

The interposer (IP80Modell) and silicon TSV chip (CC8OTSV-2, 7.3 mm square) having the interlayer filler composition applied were heat-press bonded by means of a thermal compression bonding apparatus “Flip-chip bonder (FC3000S)” manufactured by Toray Engineering Co., Ltd. at the head temperature of 250° C., at the stage temperature of 250° C., for a bonding time of 5 seconds, at a bonding pressure of 20 N (3.8 Kgf/cm2).

Then, the interlayer filler composition was applied to the above bonded substrates in an amount of about 8 mg (about 16 mg/cm2 per effective area) while heating at 70° C., and further, a silicon solder bump chip (CC80Modell, 7.3 mm square), was heat-press bonded under the same conditions. Then, by heating for 1 hour at 180° C. for curing, a semiconductor device was produced.

As a result, voids did not exist, and electrical conduction was confirmed. The appearance shape and cross-sectional photographs are shown in FIGS. 2A and 2B.

TABLE 1

| | Interlayer filler composition blend (parts by weight) | | | | | | | | | |
|---|---|---|---|---|---|---|---|---|---|---|
| | Epoxy resin (A) | | Curing agent (B) | | Filler (C) | | Flux (D) | | Curing accelerator (E) | |
| | Type | Amount | Type | Amount | Type | Amount | Type | Amount | Type | Amount |
| Ex. 1 | A1 | 100 | B1 | 80 | C1/C2/C3 | 148/347/225 | D1 | 5.4 | E1 | 27 |
| Ex. 2 | A1/A2 | 50/50 | B1 | 80 | C1/C2/C3 | 148/347/225 | D1 | 1.8 | E1 | 27 |
| Ex. 3 | A1/A2 | 50/50 | B1 | 80 | C6 | 270 | D2 | 1.8 | E1 | 27 |
| Ex. 4 | A1/A2 | 50/50 | B1 | 80 | C6 | 270 | D3 | 1.8 | E1 | 27 |
| Ex. 5 | A1/A2 | 50/50 | B1 | 80 | C6 | 270 | D3 | 9.0 | E1 | 27 |
| Ex. 6 | A1/A2 | 50/50 | B1 | 80 | C6 | 270 | D4 | 5.4 | E1 | 27 |
| Ex. 7 | A1/A2 | 50/50 | B1 | 80 | C6 | 270 | D3 | 1.8 | E1 | 27 |
| Ex. 8 | A1/A2 | 50/50 | B1 | 80 | C6 | 270 | D3 | 1.8 | E1 | 27 |
| Ex. 9 | A1/A2 | 50/50 | B1 | 80 | C7/C8 | 473/473 | D3 | 1.8 | E1 | 27 |
| Ex. 10 | A1/A2 | 50/50 | B1 | 80 | C7 | 946 | D5 | 1.8 | E1 | 27 |
| Comp. Ex. 1 | A1 | 100 | B2/B3 | 17/27 | C4 | 218 | D2 | 1.5 | — | — |
| Comp. Ex. 2 | A1 | 100 | B2/B3 | 17/27 | C1/C2/C3 | 120/280/120 | D1 | 4.4 | — | — |
| Comp. Ex. 3 | A1 | 100 | B2/B3 | 17/27 | C5/C3 | 345/138 | D2 | 4.6 | — | — |
| Comp. Ex. 4 | A1 | 100 | B2/B3 | 17/27 | C4 | 128 | D1 | 0.7 | — | — |

In Table, “—” indicates that the material was not used.

TABLE 2

| | Minimum value | | | | | | |
|---|---|---|---|---|---|---|---|
| | temperature | Viscosity (Pa · s) | | | | | |
| | (° C.) | ηₘᵢₙ | η₅₀ | η₁₂₀ | η₁₅₀ | η₅₀/η₁₂₀ | η₁₅₀/η₁₂₀ |
| Ex. 1 | 122 | 1.3 | 110 | 1.4 | 2.0E+06 | 79 | 1.4E+06 |
| Ex. 2 | 134 | 17.0 | 1.183 | 74 | 9.5E+04 | 16 | 1.284 |
| Ex. 3 | 118 | 0.1 | 89 | 0.2 | 1.6E+04 | 406 | 8.0E+04 |
| Ex. 4 | 125 | 1.3 | 3.9 | 0.2 | 1,2E+04 | 17 | 6.0E+04 |
| Ex. 5 | 111 | 1.3 | 157 | 4.8 | 2.2E+06 | 33 | 4.6E+05 |
| Ex. 6 | 110 | 0.5 | 133 | 0.7 | 2.0E+06 | 202 | 2.9E+06 |
| Ex. 7 | 125 | 1.3 | 3.9 | 0.2 | 1.2E+04 | 17 | 6.0E+04 |
| Ex. 8 | 125 | 1.3 | 3.9 | 0.2 | 1.2E+04 | 17 | 6.0E+04 |
| Ex. 9 | 112 | 2.8 | 64 | 3.4 | 2.5E+06 | 19 | 7.4E+05 |
| Ex. 10 | 116 | 7.3 | 11 | 0.7 | 8.9E+05 | 15 | 1.3E+06 |
| Comp. Ex. 1 | 75 | 22 | 54 | 93 | 162 | 0.6 | 1.7 |
| Comp. Ex. 2 | 140 | 2.5 | 65 | 3.2 | 2.7 | 20 | 0.8 |
| Comp. Ex. 3 | 128 | 1.8 | 96 | 1.9 | 2.7 | 51 | 1.4 |
| Comp. Ex. 4 | 154 | 0.5 | 13 | 0.9 | 0.6 | 14 | 0.7 |

TABLE 3

| | | At the time | | At the time | | | | | | | | | |
|---|---|---|---|---|---|---|---|---|---|---|---|---|---|
| | | of contact | | of bonding | | | Heat | | Bonding properties | | | | |
| | | Head | Stage | Head | Stage | Pressing | pressing | | | | Outer | Inner | |
| | Applied | temp. | temp. | temp. | temp. | force | time | | | Resis- | circum- | circum- | |
| | surface | (° C.) | (° C.) | (° C.) | (° C.) | (Kgf/cm²) | (sec) | Substrate | Voids | tance | ference | ference | Curability |
| Ex. 1 | Stage | 100 | 100 | 250 | 250 | 3.8 | 5 | Si—Si | ∘ | ∘ | 101% | 100% | ∘ |
| | side | | | | | | | | | | | | |
| Ex. 2 | Stage | 100 | 100 | 250 | 250 | 3.8 | 5 | Si—Si | ∘ | ∘ | 102% | 100% | ∘ |
| | side | | | | | | | | | | | | |
| Ex. 3 | Stage | 100 | 100 | 250 | 250 | 3.8 | 5 | Si—Si | ∘ | ∘ | 100% | 97% | ∘ |
| | side | | | | | | | | | | | | |
| Ex. 4 | Stage | 100 | 100 | 260 | 100 | 3.8 | 4 | Si- | ∘ | ∘ | 100% | 101% | ∘ |
| | side | | | | | | | organic | | | | | |
| | | | | | | | | substrate | | | | | |
| Ex. 5 | Stage | 150 | 150 | 260 | 150 | 3.8 | 5 | Si- | ∘ | ∘ | 104% | 105% | ∘ |
| | side | | | | | | | organic | | | | | |
| | | | | | | | | substrate | | | | | |
| Ex. 6 | Stage | 150 | 150 | 260 | 150 | 3.8 | 5 | Si- | ∘ | ∘ | 105% | 105% | ∘ |
| | side | | | | | | | organic | | | | | |
| | | | | | | | | substrate | | | | | |
| Ex. 7 | Head | 40 | 150 | 250 | 250 | 3.8 | 5 | Si—Si | ∘ | ∘ | 100% | 97% | ∘ |
| | side | | | | | | | | | | | | |
| Ex. 8 | Head | 40 | 200 | 250 | 250 | 3.8 | 5 | Si—Si | ∘ | ∘ | 100% | 97% | ∘ |
| | side | | | | | | | | | | | | |
| Ex. 9 | Stage | 100 | 100 | 250 | 250 | 3.8 | 5 | Si—Si | ∘ | ∘ | 101% | 101% | ∘ |
| | side | | | | | | | | | | | | |
| Ex. 10 | Stage | 100 | 100 | 250 | 250 | 3.8 | 5 | Si—Si | ∘ | ∘ | 100% | 100% | ∘ |
| | side | | | | | | | | | | | | |
| Comp. | Stage | 100 | 100 | 250 | 250 | 3.8 | 5 | Si—Si | ∘ | ∘ | 100% | 97% | × |
| Ex. 1 | side | | | | | | | | | | | | |
| Comp. | Stage | 100 | 100 | 250 | 250 | 3.8 | 5 | Si—Si | ∘ | ∘ | 100% | 97% | × |
| Ex. 2 | side | | | | | | | | | | | | |
| Comp. | Stage | 100 | 100 | 250 | 250 | 3.8 | 5 | Si—Si | ∘ | ∘ | 99% | 97% | × |
| Ex. 3 | side | | | | | | | | | | | | |
| Comp. | Stage | 150 | 150 | 260 | 150 | 3.8 | 5 | Si- | ∘ | | Conduc- | Conduc- | × |
| Ex. 4 | side | | | | | | | organic | | | tion | tion | |
| | | | | | | | | substrate | | | failure | failure | |

From the results in Examples 1 to 10 and Comparative Examples 1 to 5, it has been found that according to the present invention, good bonding properties can be obtained.

### INDUSTRIAL APPLICABILITY

A layered semiconductor device formed by using the interlayer filler composition of the present invention is excellent in reliability, and it is useful for high speed and high capacity of a semiconductor device.

This application is a continuation of PCT Application No. PCT/JP2015/078803, filed on Oct. 9, 2015, which is based upon and claims the benefit of priority from Japanese Patent Application No. 2014-209592 filed on Oct. 14, 2014. The contents of those applications are incorporated herein by reference in their entireties.

### REFERENCE SYMBOLS

1: solder bump, 2: semiconductor substrate (semiconductor chip), 3: interlayer filler composition, 5: interlayer filler composition layer, 6: electrode pad, 7: semiconductor substrate, 8: cured adhesive layer, 10: semiconductor device, 11: through-hole electrode (TSV)

1. An interlayer filler composition, comprising an epoxy resin (A), a curing agent (B) in an amount of from 30 to 120 parts by weight per 100 parts by weight of the epoxy resin (A), a filler (C) and a flux (D), having a minimum value of its viscosity at from 100 to 150° C. and satisfying the following formulae (1) and (2) simultaneously:
10<η50/η120<500 (1)
1,000<η150/η120 (2)
wherein η150, η120 and η150 represent the viscosities at 50° C., 120° C. and 150° C., respectively, of the interlayer filler composition.

2. The interlayer filler composition of claim 1, having a viscosity at 120° C. of from 0.1 to 100 Pa·s.

3. The interlayer filler composition of claim 1, further comprising a curing accelerator (E).

4. The interlayer filler composition of claim 1, wherein the curing agent (B) is an acid anhydride.

5. The interlayer filler composition of claim 1, wherein the curing agent (B) is within a range from 0.8 to 1.5 by an equivalent ratio of functional groups in the curing agent (B) to epoxy groups in the epoxy resin (A).

6. The interlayer filler composition of claim 1, wherein the curing agent (B) comprises at least one curing agent selected from the group consisting of an amine-type curing agent and an acid anhydride-type curing agent.

7. A method for producing a semiconductor device, comprising bonding a semiconductor chip having solder bumps, and a semiconductor substrate having an electrode pad, via the interlayer filler composition of claim 1 by a thermal compression bonding apparatus.

8. The method of claim 7, wherein the interlayer filler composition is used in an amount of from 1 to 50 mg/cm² per area of the semiconductor chip.

9. The method of claim 7, wherein a layer of the interlayer filler composition is formed on the semiconductor chip having solder bumps, and the solder bumps and the electrode pad are contacted at a stage temperature of the thermal compression bonding apparatus of at least 100° C. and at a head temperature of at most 100° C.

10. The method of claim 7, wherein at the time of bonding, a head temperature is from 200° C. to 500° C., a stage temperature is from 70° C. to 200° C., a pressing pressure is from 0.1 to 50 Kgf/cm², and a bonding time is from 0.1 to 30 seconds.
